(19) United States
(12) Patent Application Publication
(10) Pub. No.: US 2026/0058094 A1
(43) Pub. Date: Feb. 26, 2026

(54) METHOD FOR DEPOSITING A COATING IN PROCESS CHAMBERS

(71) Applicant: APPLIED MATERIALS, INC., Santa Clara, CA (US)

(72) Inventors: Joseph Behnke, Santa Clara, CA (US); Vahid Firouzdor, San Mateo, CA (US); Jonathan Strahle, San Franciso, CA (US); Christopher Beaudry, San Jose, CA (US)

(21) Appl. No.: 19/299,541

(22) Filed: Aug. 14, 2025

Related U.S. Application Data
(60) Provisional application No. 63/685,891, filed on Aug. 22, 2024.

(51) Int. Cl. H01J 37/317; H01J 37/32; H01L 21/687

(52) U.S. Cl. CPC H01J 37/3178; H01J 37/32495; H01L 21/68757; H01J 2237/31732

(57) ABSTRACT

A method of coating an article for a process chamber is provided. The method includes performing an ion assisted deposition (IAD) using a dual source include a first source and a second source to deposit a protective layer on at least one surface of the article. The first source includes a metal oxide and the second source includes a metal fluoride. When the IAD is performed, a ratio of the metal oxide to the metal fluoride is controlled, such that a gradient in fluoride content between a bottom of the protective layer and the top of the protective layer occurs.

### TECHNICAL FIELD

The present application claims priority to U.S. Provisional Patent Application No. 63/685,891 filed on Aug. 22, 2024. The entire contents of which are incorporated in its entirety.

### TECHNICAL FIELD

Embodiments of the present invention relate, in general, to methods for depositing a coating on an article, such as a chamber component, using an ion assisted deposition (IAD) including a dual source to deposit a protective layer, and in particular to deposit a protective layer having at least one of a fluorine gradient or a metal gradient.

### BACKGROUND

In the semiconductor industry, devices are fabricated by a number of manufacturing processes producing structures of an ever-decreasing size. Some manufacturing processes such as plasma etch and plasma clean processes expose a substrate to a high-speed stream of plasma to etch or clean the substrate. The plasma may be highly corrosive, and may corrode processing chambers and other surfaces that are exposed to the plasma.

Additionally, the chamber chemicals and plasmas used in process chambers have become more complex, requiring more complex compounds to protect the chamber components. However, these compounds can have adhesion issues depending on the material of the substrate/article. Moreover, the current deposition processes have not been able to effectively deposit each element of the complex compounds, thus resulting in less effective protection of chamber components.

### BRIEF DESCRIPTION OF THE DRAWINGS

The present invention is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber.

FIG. 2A depicts a deposition mechanism applicable to a variety of deposition techniques utilizing energetic particles such as ion assisted deposition (IAD).

FIG. 2B depicts a schematic of an IAD deposition apparatus.

FIGS. 3A-4B illustrate cross sectional side views of articles covered by one or more thin film protective layers.

FIG. 5A illustrates one embodiment of a process for forming one or more protective layers over an article.

FIG. 5B illustrates one embodiment of a process for forming a thin film protective layer over a body of an article using an IAD or PVD.

FIG. 5C illustrates one embodiment of a process for forming a thin film protective layer over a body of an article using IAD with two metallic targets of different materials.

### DETAILED DESCRIPTION OF EMBODIMENTS

Embodiments of the present disclosure provide an article such as a chamber component for an etch reactor having a thin film protective layer on one or more plasma facing surfaces of the article. The protective layer of the present disclosure may be formed on the article using ion assisted deposition (IAD) with a dual source to apply a controlled ratio of different source materials, which has been found to better distribute the source materials in the formation of complex coatings. In particular, IAD using a dual source may allow formation of a coating that has a gradient of one or more element, such as fluoride or a metal. That is, the protective layer may be a functionally graded layer that includes a change in a ratio of two metals or a change in a ratio of fluorine to metals and/or oxygen across a depth of the layer. Thus, when performing an IAD with a dual source, the protective layer may be formed on the surface of the article having 0% of an element (e.g., of fluorine or a particular metal) at a bottom of the protective layer and some amount above 0% (e.g., 1%-99%) of the element at the target thickness of the protective layer. By using a dual source with IAD, the structure of the protective coating can be controlled to improve the overall effectiveness of the coating.

In some embodiments, the protective layer may have a first source including a metal oxide and a second source including a metal fluoride. The ratio of the metal oxide to the metal fluoride is adjusted during the IAD process to cause a first fluoride content at a bottom of the protective layer, a higher second fluoride content at a top of the protective layer and a gradient in fluoride content between the bottom of the protective layer and the top of the protective layer. In other embodiments, the protective layer may have a first source including a first metal and a second source including a second metal. The ratio of the first metal and the second metal may be adjusted to cause a gradient in the metal content between the bottom of the protective layer and the top of the protective layer.

The protective layer may have a thickness up to approximately 300 μm in embodiments, and may provide plasma erosion resistance for protection of the coated article (e.g., of a coated chamber component). The protective layer may be formed on the article using ion assisted deposition (IAD) (e.g., using electron beam IAD (EB-IAD) or ion beam sputtering IAD (IBS-IAD)) with a dual source.

The protective layer may include Y₂O₃, Er₂O₃, HfO₂, ZrO₂ or a different metal oxide at a bottom of the protective layer and a complex material comprising a combination of the metal oxide and a second metal oxide and/or fluorine at a top of the protective layer. In some embodiments the different metal oxide may include a lanthanide element. The lanthanide element may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), or lutetium (Lu), or a combination thereof. In some embodiments, the protective layer comprises Y₂O₃ at a bottom of the protective layer and YₓZr_{y}O_{z} at the top of the protective layer. In some embodiments, the concentration of Zr at the top of the protective layer is 5% to about 45%. In some embodiments, the protective layer may include Y₂O₃ or YₓZr_{y}O_{z} at a bottom of the protective layer and YₐZr_{b}O_{c}F_{d} at a top of the protective layer. The protective layer improves erosion resistance which may improve the service life of the article, while reducing maintenance and manufacturing cost. The IAD coating may seal pores and cracks in the article to significantly reduce an amount of reactivity of process gases with the chamber component as well as a level of trace metal contamination. The IAD coating can also embed any loose particles that were on the article to reduce particle defects.

In an embodiment, a method is provided to coat an article of a chamber component. In some embodiments, the method may include performing an ion assisted deposition (IAD) using a dual source including a first source and a second source to deposit a protective layer on at least one surface of an article. In some embodiments, the first source may be a metal oxide and the second source may include a metal fluoride. In some embodiments, the metal oxide may include yttrium oxide (Y₂O₃), zirconium oxide (ZrO₂), hafnium oxide (HfO₂), or erbium oxide (Er₂O₃). In some embodiments, the metal fluoride may include yttrium fluoride (YF₃), zirconium fluoride (ZrF₄), hafnium fluoride (HfF₄), or erbium fluoride (ErF₃). In an embodiment, the metal oxide may be ZrO₂ and the metal fluoride may be YF₃.

In some embodiments, performing the IAD may include controlling a ratio of the metal oxide to the metal fluoride that is deposited and adjusting the ratio of the metal oxide to the metal fluoride during the IAD. When adjusting the ratio, it may cause a first fluoride content at a bottom of the protective layer, a higher second fluoride content at a top of the protective layer, and a gradient in fluoride content between the bottom of the protective layer and the top of the protective layer.

In some embodiments, the protective layer may include yttrium (Y), zirconium (Zr), hafnium (Hf), erbium (Er), or a combination thereof. In some embodiments, the protective layer may further include a lanthanide element. The lanthanide element may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), or lutetium (Lu), or a combination thereof. In some embodiments, the protective layer may include YₐZr_{b}O_{c}F_{d}.

In some embodiments, the first fluoride content at a bottom of the protective coating may be about 0% to about 30%, about 5% to about 25%, about 15% to about 25%, or about 20%. In some embodiments, the first fluoride content may be about 0%, about 10%, about 15%, about 20%, about 25%, or about 30%. In some embodiments, the higher second fluoride content may be about 40% to about 65%, about 45% to about 60%, or about 50% to about 55%.

In some embodiments, the protective layer may include yttrium, zirconium, oxygen and fluorine, with an overall fluorine concentration of about 55% to about 70%, or about 60% to about 65%, and an overall zirconium concentration of about 0.1% to about 5%, or about 1% to about 4%.

In some embodiments, the bottom of the protective layer may be deposited using first deposition parameter values for the first source and second deposition parameter values for the second source, and the top of the protective layer may be deposited using third deposition parameter values for the first source and fourth deposition parameter values for the second source. In some embodiments, the first, second, third, and fourth parameter values may include at least one of electron beam current values or electron beam energy or power values for an electron beam focused on the first and/or second sources.

In some embodiments, a fluoride gas or a fluoride plasma may be applied to at least one surface of the article to form a fluoride layer before performing the IAD using a physical vapor deposition (PVD) or chemical vapor deposition (CVD) process. By prefluorinating the surface of the article, there may be less ramp up time to prepare the processing chamber for manufacturing use.

In another embodiment, a method is provided including performing an IAD using a dual source including a first source and a second source to deposit a protective layer on at least one surface of the article. In some embodiments, the first source may include a first metal and the second source may include a second metal, wherein the IAD process may include controlling a ratio of the first metal to the second metal that is deposited. The method may further include adjusting the ratio of the first metal to the second metal during the IAD to cause varying contents of the first metal and second metal throughout the protective layer, such as a gradient in metal content between the bottom of the protective layer and the top of the protective layer.

In some embodiments, the first metal may be a first metal oxide including Y₂O₃, ZrO₂, HfO₂, or Er₂O₃. In some embodiments, the first metal and the second metal may each include a different one of Y, Zr, Hf, Er, or a combination thereof. In some embodiments, the protective layer may include Y₂O₃ at the bottom of the protective layer, YₓZr_{y}O_{z} at a top of the protective layer, and a gradient in a concentration of Zr between the bottom of the protective layer and the top of the protective layer.

In another embodiment, an article may include a protective layer that is deposited according to a method described herein. The article may be a chamber component or other surface that needs protection from a corrosive plasma in the process chamber.

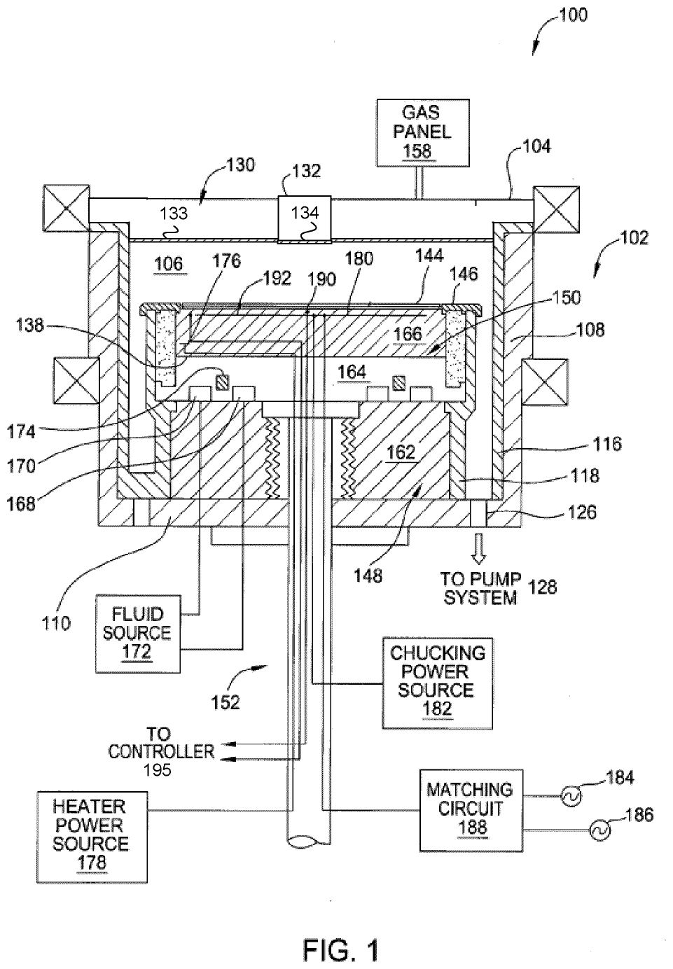

FIG. 1 is a sectional view of a semiconductor processing chamber 100 having one or more chamber components that are coated with a protective layer in accordance with embodiments of the present disclosure. The processing chamber 100 may be used for processes in which a corrosive plasma environment is provided. For example, the processing chamber 100 may be a chamber for a plasma etch reactor (also known as a plasma etcher), a plasma cleaner, a deposition chamber (e.g., a chemical vapor deposition chamber, an atomic layer deposition chamber, a physical vapor deposition chamber, an epitaxy chamber, etc.), and so forth. Examples of chamber components that may include a protective layer include a substrate support assembly 148, an electrostatic chuck (ESC) 150, a ring (e.g., a process kit ring or single ring), a chamber wall, a base, a gas distribution plate, a showerhead, a chamber liner, a liner kit, a shield, a plasma screen, a flow equalizer, a cooling base, a chamber viewport, a chamber lid 104, a nozzle, a flow equalizer (FEQ), and so on. In one particular embodiment, the protective layer is applied over a chamber lid 104 and/or a chamber nozzle 132.

The protective layer, which is described in greater detail below, is a rare earth oxide layer or a rare earth oxy-fluoride layer deposited by ion assisted deposition (IAD) using a dual source. The dual source may include a first source and a second source. The first source may include a first metal or metal oxide or metal fluoride, and the second source may include a second metal, metal oxide or metal fluoride. In some embodiments, the first source may be Y₂O₃, ZrO₂, HfO₂, or Er₂O₃. In some embodiments, the second source may be YF₃, ZrF₄, HfF₄, or ErF₃. In some embodiments, the first source and second source are each different ones of Y₂O₃, ZrO₂, HfO₂, or Er₂O₃. In some embodiments, the first source and second source are each different ones of YF₃, ZrF₄, HfF₄, or ErF₃. By using a dual source, the components of the composition may be controlled by adjusting the ratio of the first source (i.e., metal oxide) and the second source (i.e., metal fluoride) that is deposited. When IAD is performed, the ratio of the first source and the second source may be adjusted to cause a first content of a component at a bottom of the protective layer and a different content of the component at the top of the protective layer forming a gradient in some cases. For example, if the first source is a metal oxide and the second source is a metal fluoride, then the ratio of the metal oxide to the metal fluoride may be controlled when deposited. The ratio may be adjusted during IAD to cause a first fluoride content at a bottom of the protective layer, a higher second fluoride content at a top of the protective layer, and a gradient in fluoride content between the bottom of the protective layer and the top of the protective layer.

In another embodiment, the first source may be a first metal (e.g., a first metal oxide) and the second source may be a second metal (e.g., a second metal oxide), where the ratio may be adjusted during IAD to cause a gradient in metal content between the bottom of the protective layer and the top of the protective layer. For example, the protective coating may include Y₂O₃ at a bottom of the protective coating and YₓZr_{y}O_{z} at a top of the protective coating.

In some embodiments, the protective layer that is deposited by IAD may include YₐZr_{b}O_{c}F_{d}. In some embodiments, the protective layer may include Y, Zr, Hf, Er, or a combination thereof. In some embodiments, the protective layer may further include a lanthanide element. The lanthanide element may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), thulium (Tm), ytterbium (Yb), or lutetium (Lu), or a combination thereof.

In some embodiments, the protective layer is a metal oxy-fluoride layer that may include a first fluoride content near the bottom of the protective layer of about 10% to about 30%, about 15% to about 25%, or about 18% to about 22%. In some embodiments, the protective layer may include a first fluoride content near the bottom of the protective layer is about 10%, about 12%, about 15%, about 20%, about 22%, about 25%, about 28%, or about 30%. In some embodiments, the protective layer may include a second fluoride content near the top of the protective layer of about 35% to about 70%, about 40% to about 65%, or about 45% to about 60%. In some embodiments, the protective layer may include a second fluoride content near the top of the protective layer is about 35%, about 40%, about 45%, about 55%, about 60%, about 65%, or about 70%.

In some embodiments, the protective layer is a YₐZr_{b}O_{c}F_{d} layer having an overall fluoride concentration of about 50% to about 75%, about 55% to about 70%, or about 60% to about 65%. In some embodiments, the protective layer is a YₐZr_{b}O_{c}F_{d} layer having an overall zirconium concentration may be about 0.1% to about 10%, about 0.5% to about 8%, about 1% to about 5%, or about 2% to about 4%. In some embodiments, the overall fluoride concentration of the protective layer may be about 50%, about 55%, about 60%, about 65%, about 70%, or about 75%. In some embodiments, the overall zirconium concentration may be about 0.1%, about 0.5%, about 1%, about 2%, about 3%, about 4%, about 5%, about 6%, about 7%, about 8%, about 9%, or about 10%.

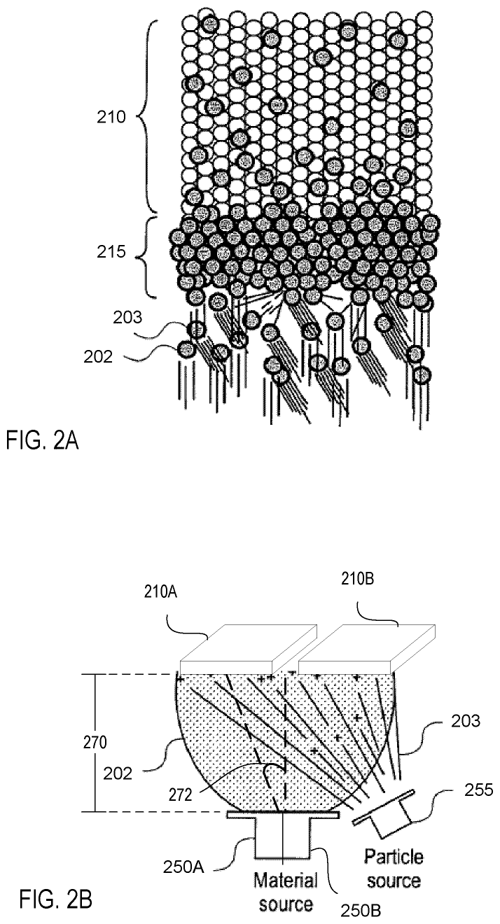

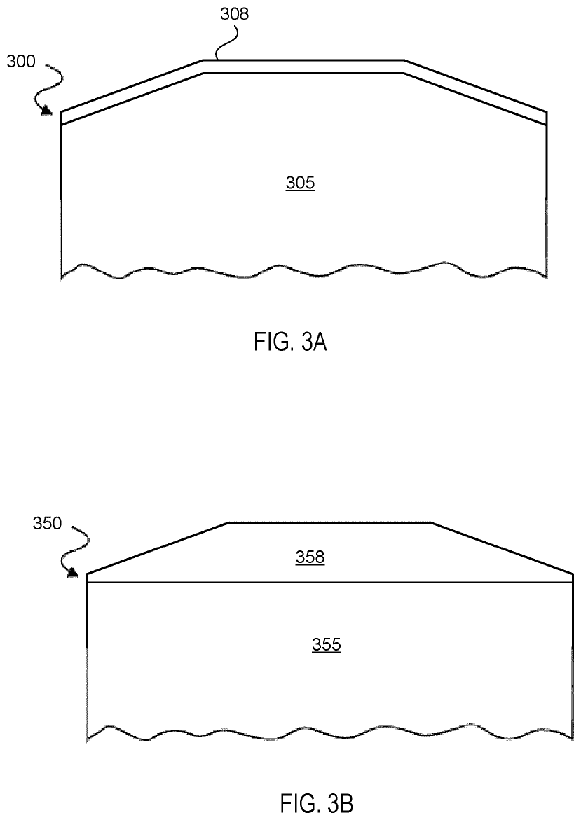

In some embodiments, the bottom of the protective layer may be deposited using first deposition parameter values for the first source and second deposition parameter values for the second source, which will be explained in more detail in FIG. 2. In some embodiments, the top of the protective layer may be deposited using third deposition parameter values for the first source and fourth deposition parameter values for the second source, as described with reference to FIG. 2. In some embodiments, the first, second, third and fourth parameter values may include at least one of beam current values or beam energy values.

The thin film protective layer may be an IAD coating applied over different ceramic articles including oxide based ceramics, nitride based ceramics and carbide based ceramics. Examples of oxide based ceramics include SiO₂ (quartz), Al₂O₃, Y₂O₃, and so on. Examples of carbide based ceramics include SiC, Si-SiC, and so on. Examples of nitride based ceramics include AlN, SiN, and so on. The thin film protective layer may also be an IAD coating applied over a plasma sprayed protective layer in some embodiments. The plasma sprayed protective layer may be Y₃Al₅O₁₂, Y₂O₃, Y₄Al₂O₉, Er₂O₃, Gd₂O₃, Er₃Al₅O₁₂, Gd₃Al₅O₁₂, a ceramic compound comprising Y₄Al₂O₉ and a solid-solution of Y₂O₃-ZrO₂, or another ceramic.

As illustrated, the lid 130 and nozzle 132 each have a thin film protective layer 133, 134, in accordance with one embodiment. However, it should be understood that any of the other chamber components, such as those listed above, may also include a thin film protective layer. For example, an inner liner and/or outer liner of the processing chamber 100 may include the thin film protective layer.

In one embodiment, the processing chamber 100 includes a chamber body 102 and a lid 130 that enclose an interior volume 106. The lid 130 may have a hole in its center, and a nozzle 132 may be inserted into the hole. The chamber body 102 may be fabricated from aluminum, stainless steel or other suitable material. The chamber body 102 generally includes sidewalls 108 and a bottom 110. Any of the lid 130, nozzle 132, sidewalls 108 and/or bottom 110 may include a plasma sprayed protective layer and/or a thin film protective layer that may act as a top coat over the plasma sprayed protective layer.

An outer liner 116 may be disposed adjacent the sidewalls 108 to protect the chamber body 102. The outer liner 116 may include a plasma sprayed protective layer and/or a IAD protective layer. In one embodiment, the outer liner 116 is fabricated from aluminum oxide. In one embodiment, the outer liner 116 is fabricated from an aluminum alloy (e.g., 6061 Aluminum) with a plasma sprayed Y₂O₃ protective layer. The IAD protective layer may act as a top coat over the Y₂O₃ protective layer on the outer liner. In an embodiment, there is no plasma spray protective layer and the IAD protective layer is included on the other liner 116.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The lid 130 may be supported on the sidewall 108 of the chamber body 102. The lid 130 may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the nozzle 132. The lid 130 may be a ceramic such as Al₂O₃, Y₂O₃, YAG, SiO₂, AlN, SiN, SiC, Si—SiC, or a ceramic compound comprising Y₄Al₂O₉ and a solid-solution of Y₂O₃-ZrO₂. The nozzle 132 may also be a ceramic, such as any of those ceramics mentioned for the lid. The lid 130 and/or nozzle 132 may be coated with an IAD protective layer 133, 134, respectively.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases). A substrate support assembly 148 is disposed in the interior volume 106 of the processing chamber 100 below the lid 130. The substrate support assembly 148 holds the substrate 144 during processing. A ring 146 (e.g., a single ring) may cover a portion of the electrostatic chuck 150, and may protect the covered portion from exposure to plasma during processing. The ring 146 may be silicon or quartz in one embodiment.

An inner liner 118 may be coated on the periphery of the substrate support assembly 148. The inner liner 118 may be a halogen-containing gas resist material such as those discussed with reference to the outer liner 116. In one embodiment, the inner liner 118 may be fabricated from the same materials of the outer liner 116. Additionally, the inner liner 118 may be coated with a plasma sprayed protective layer and/or an IAD deposited thin film protective layer. In an embodiment, the inner liner 118 does not include a plasma sprayed protective layer, but only an IAD deposited protective layer.

In one embodiment, the substrate support assembly 148 includes a mounting plate 162 supporting a pedestal 152, and an electrostatic chuck 150. The electrostatic chuck 150 further includes a thermally conductive base 164 and an electrostatic puck 166 bonded to the thermally conductive base by a bond 138, which may be a silicone bond in one embodiment. The mounting plate 162 is coupled to the bottom 110 of the chamber body 102 and includes passages for routing utilities (e.g., fluids, power lines, sensor leads, etc.) to the thermally conductive base 164 and the electrostatic puck 166.

The thermally conductive base 164 and/or electrostatic puck 166 may include one or more optional embedded heating elements 176, embedded thermal isolators 174 and/or conduits 168, 170 to control a lateral temperature profile of the support assembly 148. The conduits 168, 170 may be fluidly coupled to a fluid source 172 that circulates a temperature regulating fluid through the conduits 168, 170. The embedded isolator 174 may be disposed between the conduits 168, 170 in one embodiment. The heater 176 is regulated by a heater power source 178. The conduits 168, 170 and heater 176 may be utilized to control the temperature of the thermally conductive base 164, thereby heating and/or cooling the electrostatic puck 166 and a substrate (e.g., a wafer) 144 being processed. The temperature of the electrostatic puck 166 and the thermally conductive base 164 may be monitored using a plurality of temperature sensors 190, 192, which may be monitored using a controller 195.

The electrostatic puck 166 may further include multiple gas passages such as grooves, mesas and other surface features, that may be formed in an upper surface of the puck 166. The gas passages may be fluidly coupled to a source of a heat transfer (or backside) gas such as He via holes drilled in the puck 166. In operation, the backside gas may be provided at controlled pressure into the gas passages to enhance the heat transfer between the electrostatic puck 166 and the substrate 144.

The electrostatic puck 166 includes at least one clamping electrode 180 controlled by a chucking power source 182. The electrode 180 (or other electrode disposed in the puck 166 or base 164) may further be coupled to one or more RF power sources 184, 186 through a matching circuit 188 for maintaining a plasma formed from process and/or other gases within the processing chamber 100. The sources 184, 186 are generally capable of producing RF signal having a frequency from about 50 kHz to about 3 GHz and a power of up to about 10,000 Watts.

FIG. 2A depicts a deposition mechanism applicable to a variety of deposition techniques utilizing energetic particles such as ion assisted deposition (IAD) and plasma vapor deposition (PVD). Some embodiments are discussed with reference to IAD. Exemplary IAD methods include deposition processes which incorporate ion bombardment, such as evaporation (e.g., activated reactive evaporation (ARE) or electron beam ion assisted deposition (EB-IAD)) and sputtering (e.g., ion beam sputtering ion assisted deposition (IBS-IAD)) in the presence of ion bombardment to form plasma resistant coatings as described herein. EB-IAD may be performed by evaporation. IBS-IAD may be performed by sputtering a solid target material.

As shown, the protective layer 215 is formed on an article 210 or on multiple articles 210A, 210B (FIG. 2B) by an accumulation of deposition materials 202 in the presence of energetic particles 203 such as ions (e.g., Oxygen ions or Nitrogen ions). The articles 210A, 210B may be metal (e.g., Aluminum alloys, stainless steel, etc.), ceramic (e.g., Al₂O₃, Y₂O₃, AlN, SiO₂, etc.), or polymer based materials. The articles 210A, 201B may already have a plasma spray coating such as a fluorine coating on at least one surface in some embodiments. The IAD or PVD process may be performed to provide a top coat over the plasma spray coating in some embodiments.

The deposition materials 202 may include atoms, ions, radicals, and so on. The energetic particles 203 may impinge and compact the thin film protective layer 215 as it is formed. Any of the IAD methods may be performed in the presence of a reactive gas species, such as O₂, N₂, halogens, etc. Such reactive species may burn off surface organic contaminants prior to and/or during deposition.

In one embodiment, EB-IAD is utilized to form the protective layer 215. In another embodiment, IBS-IAD is utilized to form the protective layer 215. FIG. 2B depicts a schematic of an IAD deposition apparatus. For ease, the first material source 250A will be described, but it is understood that the second material source 250B is also deposited concurrently, sequentially, or cyclically. As shown, a first material source 250A provides a flux of first deposition materials 202 while an energetic particle source 255 provides a flux of the energetic particles 203, both of which impinge upon the article 210, 210A, 210B throughout the IAD process. The energetic particle source 255 may be an Oxygen, Nitrogen or other ion source. The energetic particle source 255 may also provide other types of energetic particles such as radicals, neutrons, atoms, and nano-sized particles which come from particle generation sources (e.g., from plasma, reactive gases or from the material source that provide the deposition materials). A second material source 250B provides a flux of second deposition materials while an energetic particle source 255 provides a flux of energetic particles (). The first material source 250A and second material source 250B may be adjusted to control the ratio of materials that are being deposited to form the protective layer.

IAD sources can be calcined powders, preformed lumps (e.g., formed by green body pressing, hot pressing, and so on), a sintered body (e.g., having 50-100% density), or a machined body (e.g., can be ceramic, metal, or a metal alloy). In some embodiments, the first material source may be a first metal, a first metal oxide, or a first metal fluoride. In some embodiments, the second material source may be a second metal, a second metal oxide, or a second metal fluoride. In one example, the first material source may be Y₂O₃, ZrO₂, HfO₂, Er₂O₃, Y, Zr, Hf, Er, or a combination thereof, and the second material source may be YF₃, ZrF₄, HfF₄, or ErF₃, Y, Zr, Hf, Er, or a combination thereof. In another example, the first and second sources may each be different ones of Y₂O₃, ZrO₂, HfO₂, Er₂O₃, Y, Zr, Hf, Er, or a combination thereof. Other target materials may also be used, such as powders, calcined powders, preformed material (e.g., formed by green body pressing or hot pressing), or a machined body (e.g., fused material). In some embodiments, the first and second sources may include a lanthanide element. The lanthanide element may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), or lutetium (Lu), or a combination thereof. All of the different types of material sources 250A, B are melted into molten material sources during deposition. However, different types of starting material take different amounts of time to melt. Fused materials and/or machined bodies may melt the quickest. Preformed material melts slower than fused materials, calcined powders melt slower than preformed materials, and standard powders melt more slowly than calcined powders.

To form complex oxide compositions, various metal alloys may be used as the target material. Some example metal alloys that may be used to deposit plasma resistant rare earth oxide layers include a Yttrium Zirconium alloy; a Yttrium, Zirconium, Aluminum alloy; an Erbium Aluminum alloy, a Gadolinium Aluminum alloy; a Yttrium, Erbium, Zirconium, Aluminum alloy; a Yttrium, Erbium, Zirconium, Gadolinium, Silicon alloy; and a Yttrium, Gadolinium, Aluminum alloy.

The flow rate of the material sources 250A, 250B may be adjusted to control a fluoride content or metal content in the protective layer 215 that is formed. The flow rate or deposition rate of the different material sources 250A, 250B may be controlled based on, for example, respective electron beam power and/or electron beam current used for the different sources. In one embodiment, a low flow rate of the first material source is initially used to deposit a protective layer that has a low concentration of fluoride or metal near the bottom of the protection layer. This may minimize or eliminate any mismatch stress induced by physical property differences between the protective layer 215 and the article 210. The flow rate of the first material source may be gradually increased as the deposition process continues. The flow rate may be increased linearly, exponentially, or logarithmically during the deposition process for example. The top of the protective layer 215 may then have a high concentration of fluorine or particular metal.

IAD may utilize one or more plasmas or beams (e.g., electron beams) to provide the material and energetic ion sources. Reactive species may also be provided during deposition of the plasma resistant coating. In one embodiment, the energetic particles 203 include at least one of non-reactive species (e.g., Ar) or reactive species (e.g., O or N). For example, Oxygen ions or Nitrogen ions may be used to bombard the article 210 during the IAD deposition. These Oxygen or Nitrogen ions may additionally react with the evaporated or sputtered metal in situ. The bombardment of Oxygen or Nitrogen ions may be used instead of or in addition to the flowing of Oxygen or Nitrogen radicals into the processing chamber to react with the evaporated or sputtered metal in situ.

In further embodiments, reactive species such as CO and/or halogens (Cl, F, Br, etc.) may also be introduced during the formation of a plasma resistant coating to further increase the tendency to selectively remove deposited material most weakly bonded to the protective layer 215.

With IAD processes, the energetic particles 203 may be controlled by the energetic ion (or other particle) source 255 independently of other deposition parameters. The energy (e.g., velocity), density and incident angle of the energetic ion flux may be adjusted to control a composition, structure, crystalline orientation and/or grain size of the protective layer. Additional parameters that may be adjusted are a temperature of the article during deposition as well as the duration of the deposition.

The ion assist energy is used to densify the coating and to accelerate the deposition of the material on the surface of the substrate. Ion assist energy can be varied using both the voltage and current of the ion source. The voltage and current can be adjusted to achieve high and low coating density, to manipulate a stress of the coating and also a crystallinity of the coating. The ion assist energy may range from approximately 50-500 Volts (V) and approximately 1-50 amps (A).

Coating temperature can be controlled by using heaters to heat a deposition chamber and/or a substrate and by adjusting a deposition rate. In one embodiment, an IAD deposition chamber (and the article therein) is heated to a starting temperature of 160° C. or higher prior to deposition. In one embodiment, the starting temperature is 160° C. to 500° C. In one embodiment, the starting temperature is 200° C. to 270° C. The temperature of the chamber and of the article may then be maintained at the starting temperature during deposition. In one embodiment, the IAD chamber includes heat lamps which perform the heating. In an alternative embodiment, the IAD chamber and article are not heated. If the chamber is not heated, it will naturally increase in temperature to about 160° C. as a result of the IAD process. A higher temperature during deposition may increase a density of the protective layer but may also increase a mechanical stress of the protective layer. Active cooling can be added to the chamber to maintain a low temperature during coating. The low temperature may be maintained at any temperature at or below 160° C. down to 0° C. in one embodiment. In one embodiment, the article is cooled to maintain a temperature at or below 150° C. during deposition. The article may be maintained at or below 150° C. to prevent the plasma sprayed protective layer from delaminating from the article during the IAD deposition. Deposition temperature can be used to adjust film stress, crystallinity, and other coating properties.

Additional parameters that may be adjusted are working distance 270 and angle of incidence 272. The working distance 270 is the distance between the material source 250A, 250B and the article 210A, 210B. In one embodiment, the working distance is 0.2 to 2.0 meters, with a working distance of at or below 1.0 meters in one particular embodiment. Decreasing the working distance increases a deposition rate and increases an effectiveness of the ion energy. However, decreasing the working distance below a particular point may reduce a uniformity of the protective layer. The working distance can be varied to achieve a coating with a highest uniformity. Additionally, working distance may affect deposition rate and density of the coating. In one embodiment, a working distance of less than 1.0 meters is used to provide an increased deposition rate at the expense of introducing a non-uniformity of up to 5-10% into the thin film protective layer.

The angle of incidence is an angle at which the deposition materials 202 strike the articles 210A, 210B. The angle of incidence can be varied by changing the location and/or orientation of the substrate. In one embodiment the angle of incidence is 10-90 degrees, with an angle of incidence of about 30 degrees in one particular embodiment. By optimizing the angle of incidence, a uniform coating in three dimensional geometries can be achieved.

IAD coatings can be applied over a wide range of surface conditions with roughness from about 0.5 micro-inches (μin) to about 180 μin. However, smoother surface facilitates uniform coating coverage. The coating thickness can be up to about 1000 microns (μm).

IAD coatings can be amorphous or crystalline depending on the materials used to create the coating. Amorphous coatings are more conformal and reduce lattice mismatch induced epitaxial cracks whereas crystalline coatings are more erosion resistant.

Coating architecture can be a bi-layer or a multi-layer structure. In a bilayer architecture, an amorphous layer can be deposited as a buffer layer to minimize epitaxial cracks followed by a crystalline layer on the top which might be erosion resistant. In a multi-layer design, layer materials may be used to cause a smooth thermal gradient from the substrate to the top layer.

Co-deposition of multiple targets using multiple electron beam (e-beam) guns can be achieved to adjust the concentrations of components within the final composition of the protective layer to more effectively apply the coating and also increase effectiveness of coating. For example, each target may be bombarded by a different electron beam gun having a first source and a second source. This may increase a deposition rate and a thickness of the protective layer. The two electron beam guns may bombard the two targets simultaneously to create a complex ceramic compound. Accordingly, two different sources may be used rather than a single source to form a complex ceramic compound.

Post coating heat treatment can be used to achieve improved coating properties. For example, it can be used to convert an amorphous coating to a crystalline coating with higher erosion resistance. Another example is to improve the coating to substrate bonding strength by formation of a reaction zone or transition layer.

In one embodiment, articles are processed in parallel in an IAD chamber. For example, up to five lids and/or nozzles may be processed in parallel in one embodiment. Each article may be supported by a different fixture. Alternatively, a single fixture may be configured to hold multiple articles. The fixtures may move the supported articles during deposition.

In one embodiment, a fixture to hold an article such as a chamber liner can be designed out of metal components such as cold rolled steel or ceramics such as Al₂O₃, Y₂O_{3,} etc. The fixture may be used to support the chamber liner above or below the material source and electron beam gun. The fixture can have a chucking ability to chuck the lid and/or nozzle for safer and easier handling as well as during coating. Also, the fixture can have a feature to orient or align the chamber liner. In one embodiment, the fixture can be repositioned and/or rotated about one or more axes to change an orientation of the supported chamber liner to the source material. The fixture may also be repositioned to change a working distance and/or angle of incidence before and/or during deposition. The fixture can have cooling or heating channels to control the article temperature during coating. The ability or reposition and rotate the chamber liner may enable maximum coating coverage of 3D surfaces such as holes since IAD is a line of sight process.

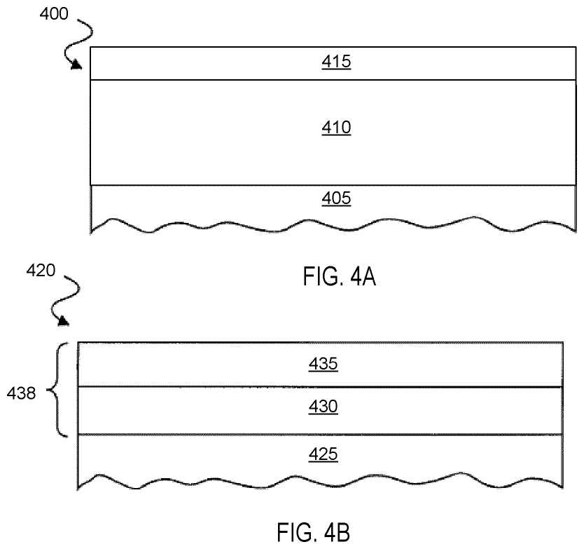

FIGS. 3A-4B illustrate cross sectional side views of articles (e.g., chamber components) covered by a protective layer. Referring to FIG. 3A, at least a portion of a base or body 305 of an article 300 is coated by a protective layer 308. The article 300 may be a chamber component, such as a substrate support assembly, an electrostatic chuck (ESC), a ring (e.g., a process kit ring or single ring), a chamber wall, a base, a gas distribution plate or showerhead, a chamber liner, a liner kit, a shield, a plasma screen, a flow equalizer, a cooling base, a chamber viewport, a chamber lid, and so on. The body 305 of the article 300 may be a metal, a ceramic, a metal-ceramic composite, a polymer, or a polymer-ceramic composite.

Various chamber components are composed of different materials. For example, an electrostatic chuck may be composed of a ceramic such as Al₂O₃ (alumina), AlN (aluminum nitride), TiO (titanium oxide), TiN (titanium nitride) or SiC (silicon carbide) bonded to an anodized aluminum base. Al₂O₃, AlN and anodized aluminum have poor plasma erosion resistance. When exposed to a plasma environment with a Fluorine chemistry and/or reducing chemistry, an electrostatic puck of an electrostatic chuck may exhibit degraded wafer chucking, increased He leakage rate, wafer front-side and back-side particle production and on-wafer metal contamination after about 50 radio frequency hours (RFHrs) of processing. A radio frequency hour is an hour of processing.

A lid process chamber may be a sintered ceramic such as Al₂O₃ since Al₂O₃ has a high flexural strength and high thermal conductivity. However, Al₂O₃ exposed to Fluorine chemistries forms AlF particles as well as aluminum metal contamination on wafers. Some chamber lids have a thick film protective layer on a plasma facing side to minimize particle generation and metal contamination and to prolong the life of the lid. However, most thick-film coatings have inherent cracks and pores that might degrade on-wafer defect performance.

A process kit ring and a single ring are used to seal and/or protect other chamber components, and are typically manufactured from quartz or silicon. These rings may be disposed around a supported substrate (e.g., a wafer) to ensure a uniform plasma density (and thus uniform etching). However, quartz and silicon have very high erosion rates under various etch chemistries (e.g., plasma etch chemistries). Additionally, such rings may cause particle contamination when exposed to plasma chemistries. The process kit ring and single ring may also consist of sintered ceramics such as YAG and or ceramic compound comprising Y₄Al₂O₉ and a solid-solution of Y₂O₃-ZrO₂.

The showerhead for an etcher used to perform dielectric etch processes is typically made of anodized aluminum bonded to a SiC faceplate. When such a showerhead is exposed to plasma chemistries including fluorine, AlF may form due to plasma interaction with the anodized aluminum base. Additionally, a high erosion rate of the anodized aluminum base may lead to arcing and ultimately reduce a mean time between cleaning for the showerhead.

A chamber viewport (also known as an endpoint window) is a transparent component typically made of quartz or sapphire. Various optical sensors may be protected by the viewport, and may make optical sensor readings through the viewport. Additionally, a viewport may enable a user to visually inspect or view wafers during processing. Both quartz and sapphire have poor plasma erosion resistance. As the plasma chemistry erodes and roughens the viewport, the optical properties of the viewport change. For example, the viewport may become cloudy and/or an optical signal passing through the viewport may become skewed. This may impair an ability of the optical sensors to collect accurate readings. However, thick film protective layers may be inappropriate for use on the viewport because these coatings may occlude the viewport.

Chamber liners are conventionally made out of an aluminum alloy (e.g., 6061 Aluminum) with a plasma sprayed Yttrium based coating for erosion and corrosion protection. The plasma spray coating is a rough porous coating with a significant amount of cracking, pores and loose particles. Process gasses may penetrate the plasma sprayed coating via the cracks and holes to react with the aluminum alloy. This introduces metal contamination inside of the chamber. Additionally, the porous plasma sprayed coating may absorb process gasses during processing. The absorption of process gasses may occur at the initiation of a process, and may reduce an amount of process gasses that are available for processing a first few wafers. This effect is known as the “first wafer effect.” The first wafer effect may be minimized or eliminated by applying a top coat of a thin film protective layer over the plasma sprayed coating.

The examples provided above set forth just a few chamber components whose performance may be improved by use of a thin film protective layer as set forth in embodiments herein.

Referring back to FIG. 3A, a body 305 of the article 300 may include one or more surface features, such as the mesa illustrated in FIG. 3A. For an electrostatic chuck, surface features may include mesas, sealing bands, gas channels, helium holes, and so forth. For a showerhead, surface features may include a bond line, hundreds or thousands of holes for gas distribution, divots or bumps around gas distribution holes, and so forth. Other chamber components may have other surface features.

The protective layer 308 formed on the body 305 may conform to the surface features of the body 305. As shown, the protective layer 308 maintains a relative shape of the upper surface of the body 305 (e.g., telegraphing the shapes of the mesa). Additionally, the coating may be thin enough so as not to plug holes in the showerhead or He holes in the electrostatic chuck. In one embodiment, the protective layer 308 has a thickness of below about 1000 microns. In one embodiment, the protective layer 308 has a thickness of below about 50 microns. In a further embodiment, the protective layer has a thickness of below about 20 microns. In a further embodiment, the protective layer has a thickness of between about 0.5 microns to about 7 microns.

The thin film protective layer 308 is a deposited ceramic layer that may be formed on the body 305 of the article 300 using an ion assisted deposition (IAD) process. The IAD deposited thin film protective layer 308 may have a relatively low film stress (e.g., as compared to a film stress caused by plasma spraying or sputtering). The relatively low film stress may cause the lower surface of the body 305 to be very flat, with a curvature of less than about 50 microns over the entire body for a body with a 12 inch diameter. The IAD deposited thin film protective layer 308 may additionally have a porosity that is less than 1%, and less than about 0.1% in some embodiments. Therefore, the IAD deposited protective layer is a dense structure, which can have performance benefits for application on a chamber component. Additionally, the IAD deposited protective layer 308 may be deposited without first roughening the upper surface of the body 305 or performing other time consuming surface preparation steps. Since roughening the body may reduce a breakdown voltage of the body 305, the ability to apply the thin film protective layer 308 without first roughening the body 305 may be beneficial for some applications (e.g., for an electrostatic chuck).

FIG. 3B illustrates a cross sectional side view of one embodiment of an article 350 having a body 355 coated by a protective layer 358. As shown, the body 355 may be devoid of features. In one embodiment, the body 355 is polished prior to deposition of the protective layer 358. Rather than having features in the body 355, features may be formed in the thin film protective layer 358. For example, the thin film protective layer 358 may be masked and then etched or bead blasted to remove unmasked portions of the thin film protective layer 358. The features can also be formed by masking the substrate and then applying the thin coating. Formed features may include mesas, channels, seal rings, exposed bond lines (e.g., of a showerhead), and so forth. Additionally, holes may be drilled in the thin film protective layer, such as by laser drilling. If features are to be formed in the protective layer 358, the protective layer should preferably have a thickness that is great enough to accommodate the features. For example, if 12μm mesas are to be formed in the thin film protective layer, then the protective layer 358 should have a thickness that is greater than 12μm. In other embodiments, some features may be formed in the body 355, and other features may be formed in the protective layer 358.

FIG. 4A illustrates a cross sectional side view of one embodiment of an article 400 having a thick protective layer 410 and a thin film protective layer 415 coating at least one surface of a body 405. The thick protective layer 410 may be a fluoride layer.

The thick protective layer 410 may have been thermally sprayed (e.g., plasma sprayed) onto the body 405. An upper surface of the body 405 may be roughened prior to plasma spraying the thick film protective layer onto it. The roughening may be performed, for example, by bead blasting the body 405. Roughening the upper surface of the body provides anchor points to create a mechanical bond between the plasma sprayed thick film protective layer and the body 405 for better adhesion. The thick film protective layer may have an as sprayed thickness of up to about 200 microns or thicker, and may be ground down to a final thickness of approximately 50 microns in some embodiments. A plasma sprayed thick film protective layer may have a porosity of about 2-4%.

Alternatively, the thick protective layer 410 may be a bulk sintered ceramic fluoride that has been bonded to the body 405. The thick protective layer 410 may be provided, for example, as a thin ceramic wafer having a thickness of approximately 200 microns.

The thin film protective layer 415 may be applied over the thick protective layer 410 using IAD. The thin film protective layer 415 may act as a top coat, and may act as an erosion resistant barrier and seal an exposed surface of the thick protective layer 410 (e.g., seal inherent surface cracks and pores in the thick protective layer 410).

FIG. 4B illustrates a cross sectional side view of one embodiment of an article 420 having a thin film protective layer stack 438 deposited over a body 425 of the article 420. Each thin film protective layer 430, 435 in the thin film protective layer stack 438 may be one of the complex ceramic compounds described above. In one embodiment, the same complex ceramic compound is not used for two adjacent thin film protective layers. However, in another embodiment adjacent layers may be composed of the same complex ceramic compound.

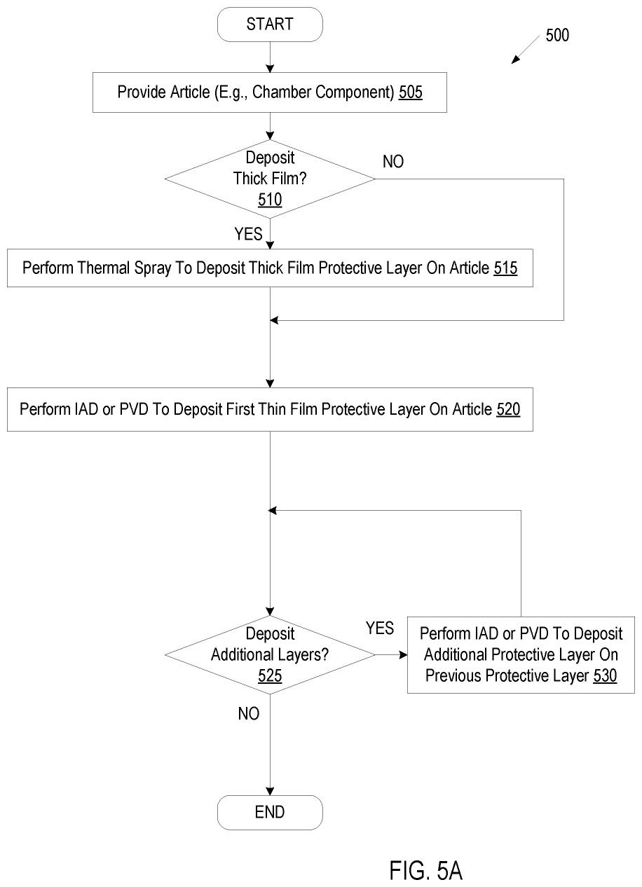

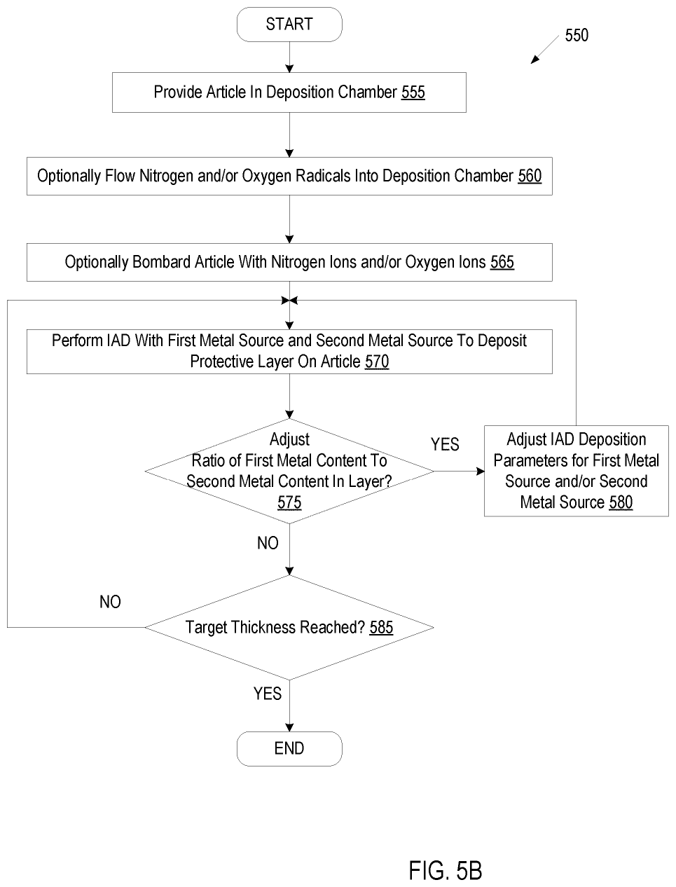

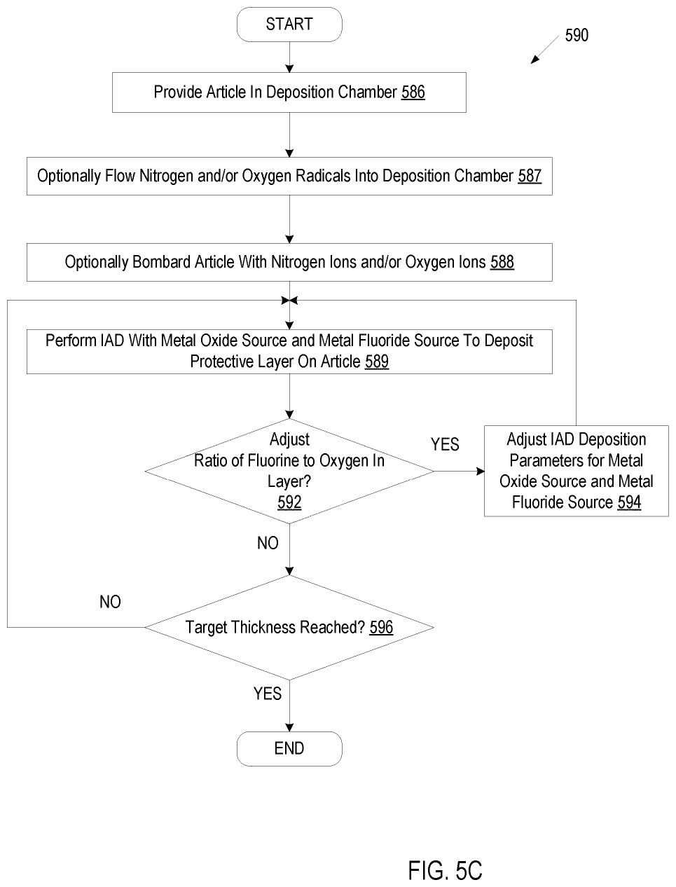

FIG. 5A illustrates one embodiment of a process 500 for forming a thin film protective layer over a body of an article such as a chamber component. At block 505 of process 500, an article is provided. At block 510, a determination is made of whether or not to deposit a thick film protective layer onto the article. If a thick film protective layer is to be formed, the method proceeds to block 515. Otherwise, the method continues to block 520.

At block 515, a thermal spray process (e.g., a plasma spray process) is performed to deposit a thick film protective layer onto the article. Prior to performing the thermal spray process, the body of the article may be roughened in some embodiments. The thick film protective layer may be any plasma resistant ceramic including a fluoride. After the thick film protective layer is formed, for some applications surface features are formed on a surface of the thick film protective layer. For example, if the article is an ESC, then mesas and He holes may be formed. In an alternative embodiment, a plasma resistant ceramic disc or other ceramic structure may be bonded to the body of the article rather than spraying a thick film protective layer.

At block 520, IAD is performed to deposit a thin film protective layer on the body of the article. If a thick film protective layer was formed at block 515, then the thin film protective layer may be formed over the thick film protective layer as a top coat. In one embodiment, chamber surface preparation is performed prior to performing IAD to deposit the thin film protective layer. For example, ion guns can prepare a surface of the article by using Oxygen and/or Argon ions to burn surface organic contamination and disperse remaining surface particles.

The thin film protective layer may be YₐZr_{b}F_{c}O_{d} or any of the other plasma resistant ceramics described herein. The thin film protective layer may have an internal gradient of one or more materials (e.g., of a metal and/or of fluorine), and may be deposited using dual sources as described herein. A deposition rate for the first source and the second source may be about 0.25-10 Angstroms per second (A/s), and may be varied by tuning deposition parameters. In one embodiment, different deposition rates are used for the first source and second source to form the thin film protective layer.

In one embodiment, the article is cooled during deposition of the thin film protective layer to maintain a temperature of the article at or below approximately 150° C. In one embodiment, a working distance between a target material and the article is set to less than one meter.

In one embodiment, one or more regions of the article that will exhibit a high erosion rate relative to other regions of the article are identified. The article is then masked with a mask that exposed the identified one or more regions. The IAD deposition is then performed to form the thin film protective layer at the identified one or more regions.

At block 525, a determination is made regarding whether to deposit any additional thin film protective layers. If an additional thin film protective layer is to be deposited, the process continues to block 530. At block 530, another thin film protective layer is formed over the first thin film protective layer. The other thin film protective layer may be composed of a ceramic that is different than a ceramic of the first thin film protective layer. The method then returns to block 525. If at block 525 no additional thin film protective layers are to be applied, the process ends. After any of the thin film protective layers is deposited, surface features may be formed in that thin film protective layer.

FIG. 5B illustrates one embodiment of a process 550 for forming a thin film protective layer over a body of an article using IAD with two metallic targets of different materials. At block 555 of process 550, an article is provided in a deposition chamber. The article may be any of the aforementioned process chamber components. At block 560, Nitrogen or Oxygen radicals may optionally be flowed into the deposition chamber at a flow rate. At block 565, Nitrogen or Oxygen ions may optionally be used to bombard the article.

At block 570, IAD is performed with a dual source including a first source and a second source as described above to deposit a protective layer on the article. An electron beam vaporizes or sputters the first and second source at different rates. A concentration of a first material (e.g., a first metal) from the first source relative to a second material (e.g., a second metal) from the second source may be based on respective deposition parameters (e.g., electron beam power and/or current) used for the an electron beam directed at the first source and the second source. In embodiments, a first metal source may be a pure metal (e.g., with no oxygen or fluorine), may be a metal oxide, or may be a metal fluoride. In embodiments, the second metal source may be a pure metal (e.g., with no oxygen or fluorine), may be a metal oxide, or may be a metal fluoride. A composition of the second metal source may be different from a composition of the first metal source.

In some embodiments, in which oxygen or nitrogen radicals and/or ions are used to bombard the surface of the article during IAD deposition, the vaporized or sputtered source materials react with the Nitrogen or Oxygen radicals and/or ions to form a complex ceramic in situ. If nitrogen radicals and/or ions are used, then the complex ceramic will be a nitride. If Oxygen radicals and/or ions are used, then the complex ceramic will be an oxide.

At block 575, a determination is made of whether to adjust a ratio of the first metal content of the first metal source relative to the second metal content of the second metal source in the coating/layer. If the relative concentrations of the first and second metal content are to change for the layer being deposited, the method proceeds to block 580. Otherwise, the method continues to block 585.

At block 580, the deposition parameters for the first source and/or second source are adjusted. This may include, for example, increasing the beam power and/or beam current for one metal source and/or reducing the beam power and/or beam current for the other metal source. The process then returns to block 570.

At block 585, a determination is made of whether the thin film protective layer has reached a target thickness. If a target thickness has been reached, the process terminates. If a target thickness has not been reached, the process returns to block 570.

FIG. 5C illustrates one embodiment of a process 590 for forming a thin film protective layer over a body of an article using IAD with two metallic targets of different materials. At block 586 of process 590, an article is provided in a deposition chamber. The article may be any of the aforementioned process chamber components. At block 587, Nitrogen or Oxygen radicals may optionally be flowed into the deposition chamber at a flow rate. At block 588, Nitrogen or Oxygen ions may optionally be used to bombard the article.

At block 589, IAD is performed with a dual source including a first source and a second source as described above to deposit a protective layer on the article. An electron beam vaporizes or sputters the first and second source at different rates. A concentration of a first material (e.g., a first metal) from the first source relative to a second material (e.g., a second metal) from the second source may be based on respective deposition parameters (e.g., electron beam power and/or current) used for the electron beam directed at the first source and the second source. In embodiments, a first metal source may be a pure metal (e.g., with no oxygen or fluorine), may be a metal oxide, or may be a metal fluoride. In embodiments, the second metal source may be a pure metal (e.g., with no oxygen or fluorine), may be a metal oxide, or may be a metal fluoride. A composition of the second metal source may be different from a composition of the first metal source.

In some embodiments, in which oxygen or nitrogen radicals and/or ions are used to bombard the surface of the article during IAD deposition, the vaporized or sputtered source materials react with the Nitrogen or Oxygen radicals and/or ions to form a complex ceramic in situ. If nitrogen radicals and/or ions are used, then the complex ceramic will be a nitride. If Oxygen radicals and/or ions are used, then the complex ceramic will be an oxide.

At block 592, a determination is made of whether to adjust a ratio of the fluorine content when compared to the source being deposited in the coating/layer. If the relative concentrations of the fluorine are to change for the layer being deposited, the method proceeds to block 594. Otherwise, the method continues to block 596.

At block 596, the deposition parameters for the first source and/or second source are adjusted. This may include, for example, increasing the beam power and/or beam current for one metal source and/or reducing the beam power and/or beam current for the other metal source. The process then returns to block 589.

At block 596, a determination is made of whether the thin film protective layer has reached a target thickness. If a target thickness has been reached, the process terminates. If a target thickness has not been reached, the process returns to block 589.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or. ” When the term “about” or “approximately” is used herein, this is intended to mean that the nominal value presented is precise within ±30%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

A method of coating an article for a process chamber is provided. The method includes performing an ion assisted deposition (IAD) using a dual source include a first source and a second source to deposit a protective layer on at least one surface of the article. The first source includes a metal oxide and the second source includes a metal fluoride. When the IAD is performed, a ratio of the metal oxide to the metal fluoride is controlled, such that a gradient in fluoride content between a bottom of the protective layer and the top of the protective layer occurs.

What is claimed is:

1. A method comprising:
performing an ion assisted deposition (IAD) using a dual source comprising a first source and a second source to deposit a protective layer on at least one surface of an article, wherein the first source comprises a metal oxide and the second source comprises a metal fluoride, and wherein performing the IAD comprises controlling a ratio of the metal oxide to the metal fluoride that is deposited; and
adjusting the ratio of the metal oxide to the metal fluoride during the IAD to cause a first fluoride content at a bottom of the protective layer, a higher second fluoride content at a top of the protective layer, and a gradient in fluoride content between the bottom of the protective layer and the top of the protective layer.

2. The method of claim 1, wherein the metal oxide comprises yttrium oxide (Y₂O₃), zirconium oxide (ZrO), hafnium oxide (HfO₂), or erbium oxide (Er₂O₃).

3. The method of claim 1, wherein the metal fluoride comprises yttrium fluoride (YF₃), zirconium fluoride (ZrF₄), hafnium fluoride (HfF₄), or erbium fluoride (ErF₃).

4. The method of claim 1, wherein the protective layer comprises yttrium (Y), zirconium (Zr), hafnium (Hf), erbium (Er), or a combination thereof.

5. The method of claim 1, wherein the protective layer comprises YₐZr_{b}O_{c}F_{d}.

6. The method of claim 1, wherein the first fluoride content is about 10% to about 30% and the higher second fluoride content of about 40% to about 65%.

7. The method of claim 1, wherein the metal oxide is ZrO₂ and the metal fluoride is YF₃.

8. The method of claim 7, wherein the protective layer comprises an overall fluoride concentration of about 55% to about 70%, and an overall zirconium concentration of about 0.1% to about 5%.

9. The method of claim 1, wherein the bottom of the protective layer is deposited using first deposition parameter values for the first source and second deposition parameter values for the second source, and wherein the top of the protective layer is deposited using third deposition parameter values for the first source and fourth deposition parameter values for the second source.

10. The method of claim 9, wherein the first, second, third and fourth parameter values comprise at least one of ion beam current values or ion beam energy values.

11. A method comprising:
performing an ion assisted deposited (IAD) using a dual source comprising a first source and a second source to deposit a protective layer on at least one surface of an article, wherein the first source comprises a first metal and the second source comprises a second metal, and wherein performing the IAD comprises controlling a ratio of the first metal to the second metal that is deposited; and
adjusting the ratio of the first metal to the second metal during the IAD to cause a gradient in metal content between a bottom of the protective layer and the top of the protective layer.

12. The method of claim 11, wherein the first metal is a first metal oxide comprising Y₂O₃, ZrO₂, HfO₂, or Er₂O₃.

13. The method of claim 11, wherein the first metal and the second metal each comprise a different one of Y, Zr, Hf, Er, or a combination thereof.

14. The method of claim 11, wherein the protective layer comprises Y₂O₃ at the bottom of the protective layer, YₓZr_{y}O_{z} at a top of the protective layer, and a gradient in a concentration of Zr between the bottom of the protective layer and the top of the protective layer.

15. A chamber component comprising:
a body;
a protective layer on a surface of the body comprising a first fluoride content at a bottom of the protective layer and a higher second fluoride content at a top of the protective layer, and a gradient in fluoride content between the bottom of the protective layer and the top of the protective layer, wherein the protective layer is deposited using an ion assisted deposition (IAD) using a dual source comprising a first source and a second source.

16. The chamber component of claim 15, wherein the first source comprises a metal oxide and the second source comprises a metal fluoride.

17. The chamber component of claim 16, wherein the metal oxide comprises yttrium oxide (Y₂O₃), zirconium oxide (ZrO), hafnium oxide (HfO₂), or erbium oxide (Er₂O₃).

18. The chamber component of claim 16, wherein the metal fluoride comprises yttrium fluoride (YF₃), zirconium fluoride (ZrF₄), hafnium fluoride (HfF₄), or erbium fluoride (ErF₃).

19. The chamber component of claim 15, wherein the protective layer comprises yttrium (Y), zirconium (Zr), hafnium (Hf), erbium (Er), or a combination thereof.

20. The chamber component of claim 15, wherein the first fluoride content is about 10% to about 30% and the higher second fluoride content of about 40% to about 65%.
